(19) United States
(12) Patent Application Publication
(10) Pub. No.: US 2009/0020833 A1
(43) Pub. Date: Jan. 22, 2009

(54) SEMICONDUCTOR DEVICE AND METHOD OF FABRICATING THE SAME

(76) Inventor: Jin-Ha Park, Gangnam-gu (KR)

Correspondence Address: SHERR & VAUGHN, PLLC, 620 HERNDON PARKWAY, SUITE 200, HERNDON, VA, 20170, US

(21) Appl. No.: 12/135,269

(22) Filed: Jun. 9, 2008

(30) Foreign Application Priority Data
Jul. 18, 2007 (KR) 10-2007-0071613

(51) Int. Cl. H01L 49/00; H01L 21/336

(52) U.S. Cl. 257/408; 438/303; 257/E49.001; 257/E21.409

(57) ABSTRACT

A method of fabricating a semiconductor device includes forming first spacers formed of a TEOS layer and second spacers formed of a first nitride layer on sidewalls of a gate electrode formed on a semiconductor substrate, and then forming source/drain regions in the semiconductor substrate using the first and second spacers and the gate electrode as masks, and then removing the second spacers, and then depositing a second nitride layer on an entire surface of the semiconductor substrate, and then implanting ions into the second nitride layer to generate compressive stress, and then etching the second nitride layer to form barrier nitride layers on the side walls of the first spacers. Because the barrier nitride has compressive stress, it is possible to prevent the movement of mobile ions, minimize influence on charge loss and charge gain in a flash memory device, and enhance a retention characteristic.

The present application claims priority under 35 U.S.C. 119 to Korean Patent Application No. 10-2007-0071613 (filed on Jul. 18, 2007), which is hereby incorporated by reference in its entirety.

### BACKGROUND

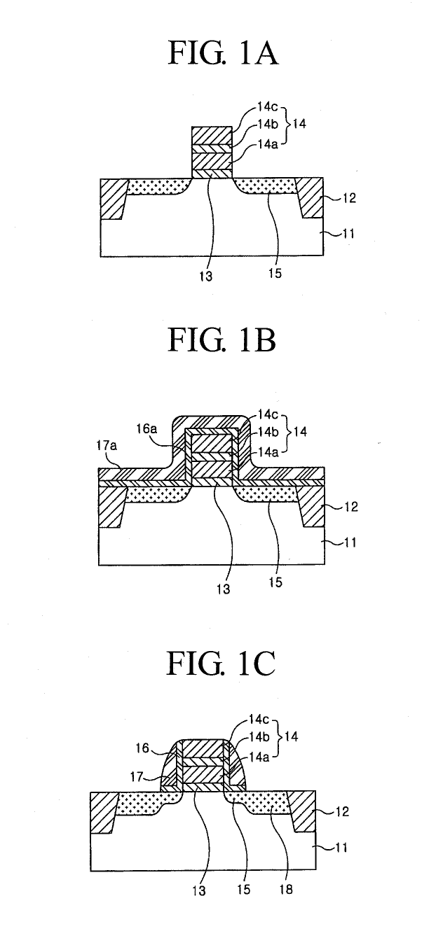

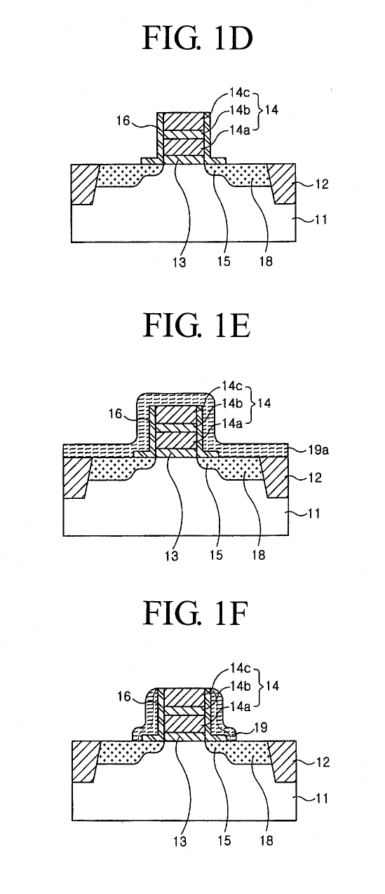

As illustrated in drawing FIG. 1A, a fabricating process for a semiconductor device such as a NOR flash memory may include forming the following: isolation layers 12 having a shallow trench isolation (STI) structure in semiconductor substrate 11, gate insulating layer 13 and gate electrode 14 composed of first polysilicon layer 14a, insulating layer 14b and second polysilicon layer 14c in an active region limited by isolation layers 12. Lightly doped drain (LDD) regions 15 may then be formed using gate electrode 14 as a mask.

As illustrated in example FIG. 1B, tetraethyl orthosilicate (TEOS) layer 16a and first nitride layer 17a may then be sequentially deposited on and/or over the resultant structure of substrate 11 including LDD regions 15.

As illustrated in example FIG. 1C, first spacers 16 formed of TEOS layer 16a and second spacers 17 formed of first nitride layer 17a may then be formed on the sides of gate insulating layer 13 and gate electrode 14 by performing reactive ion etch (RIE) on first nitride layer 17a and TEOS layer 16a. Source/drain impurities may then be implanted into the entire surface of semiconductor substrate 11 using first and second spacers 16 and 17 and gate electrode 14 as masks to form source/drain regions 18 connected to LDD regions 15 in semiconductor substrate 11 on both sides of gate electrode 14.

As illustrated in example FIG. 1D, in order to prevent the generation of a void when a gap is filled with an interlayer insulating layer on the resultant structure of substrate 11, second spacers 17 are removed.

As illustrated in example FIG. 1E, in order to remove an under cut caused by a wet etch in a non-salicide process and a salicide process in a sequential process by removing second spacers 17, second nitride layer 19a may then be grown on and/or over the substrate resultant structure using a low pressure chemical vapor deposition (LP-CVD)

As illustrated in example FIG. 1F, barrier nitride layers 19 may then be formed on side walls of first spacers 16 by selectively etching nitride layer 19a.

As described above, a method of fabricating such a semiconductor device has a structure in which the generation of a void is prevented and second spacers formed of a nitride layer are removed in order to secure a margin when an interlayer insulating layer is formed. Therefore, retention deteriorates and, in particular, charge loss and charge gain can be caused. Meaning, a barrier nitride layer formed of LP-CVD is tensile and the tension is identically applied to first spacers formed of a TEOS layer positioned adjacent to the barrier nitride layer. Therefore, the first spacer of the TEOS layer is also tensile. In the TEOS region, a distance between barrier ribs is larger due to the tension, and mobile ions that cause charge loss and charge gain easily move in the increased space between the barrier ribs to deteriorate the retention characteristic.

### SUMMARY

Embodiments relate to a memory device and a method of fabricating the same which limits the movement of mobile ions to minimize charge loss and charge gain and to enhance a retention characteristic.

Embodiments relate to a memory device and a method of fabricating the same in which barrier nitride layers formed to protect spacers formed of a TEOS layer on the sidewalls of a gate electrode from etching of a non-salicide process and a salicide process prevent mobile ions from moving, thereby minimizing influence on charge loss and charge gain in a flash memory device and to improve the retention characteristic.

Embodiments relate to a method of fabricating a semiconductor device that can include at least one of the following steps: forming first spacers formed of a TEOS layer and second spacers formed of a first nitride layer on side walls of a gate electrode formed on and/or over a semiconductor substrate; and then forming source/drain regions in the semiconductor substrate using the first and second spacers and the gate electrode as masks; and then removing the second spacers; and then depositing a second nitride layer on and/or over an entire surface of the semiconductor substrate; and then implanting ions into the second nitride layer to generate compressive stress; and then etching the second nitride layer to form barrier nitride layers on the sidewalls of the first spacers.

Embodiments relate to a semiconductor device that can include at least one of the following: a gate electrode formed on and/or over a semiconductor substrate; first spacers of a TEOS layer formed on side walls of the gate electrode; source/drain regions formed in the semiconductor substrate; and barrier nitride layers formed to have compressive stress on sidewalls of the first spacers.

Embodiments relate to a method of fabricating a semiconductor device that can include at least one of the following steps: forming first spacers composed of a TEOS layer and second spacers composed of a first nitride layer on sidewalls of a gate electrode formed on a semiconductor substrate; and then forming source/drain regions in the semiconductor substrate using the first and second spacers and the gate electrode as masks; and then removing the second spacers; and then depositing a second nitride layer on an entire surface of the semiconductor substrate; and then implanting ions into the second nitride layer to generate compressive stress in the second nitride layer; and then etching the second nitride layer to form barrier nitride layers on sidewalls of the first spacers.

Embodiments relate to a semiconductor device that can include at least one of the following: a gate electrode formed on a semiconductor substrate; first spacers composed of a TEOS layer formed on sidewalls of the gate electrode; source/drain regions formed in the semiconductor substrate; and barrier nitride layers having compressive stress formed on sidewalls of the first spacers.

Embodiments relate to a method of fabricating a flash memory device that can include at least one of the following steps: forming first spacers and second spacers on sidewalls of a gate electrode formed on a semiconductor substrate; and then removing the second spacers; and then forming a nitride layer on an entire surface of the semiconductor substrate including the gate electrode and the first spacers; and then generating compressive stress in the nitride layer; and then forming barrier nitride layers on sidewalls of the first spacers by etching the nitride layer.

In accordance with embodiments, the barrier nitride layers formed to protect the spacers of the TEOS layer from etching during a non-salicide process and a salicide process have compressive stress using an ion implantation process, thereby preventing the mobile ions from moving and minimizing influence on charge loss and charge gain in the flash memory device, and enhancing a retention characteristic.

### DRAWINGS

Example FIGS. 1A to 1F illustrate a method of fabricating a semiconductor device.

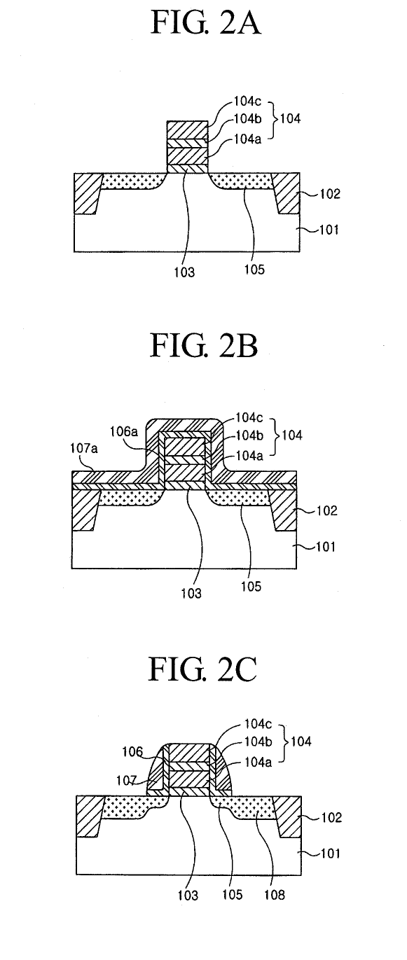

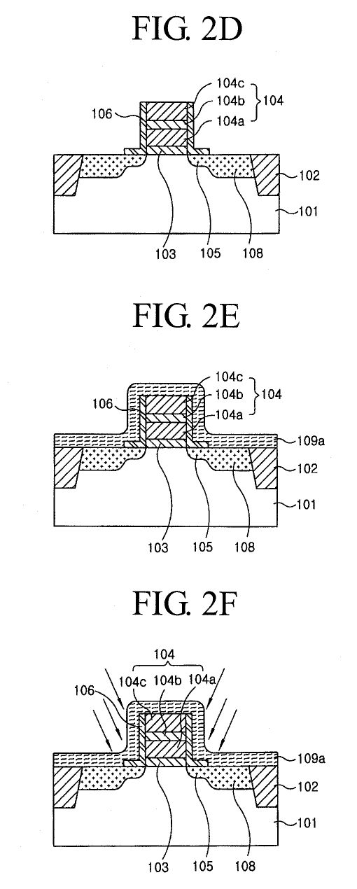

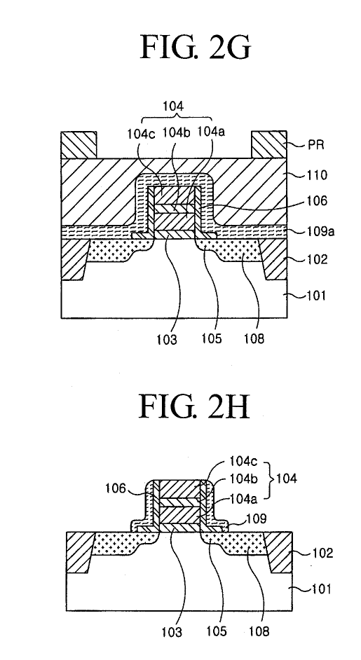

Example FIGS. 2A to 2H illustrate a method of fabricating a semiconductor device, in accordance with embodiments.

### DESCRIPTION

A method of fabricating a semiconductor device such as a flash memory device in which barrier nitride layers have compressive stress using an ion implantation process to prevent the movement of mobile ions is provided. Therefore, influence on charge loss and charge gain is minimized in the flash memory device.

As illustrated in example FIG. 2A, gate insulating layer 103 and gate electrode 104 can be formed on and/or over an active region of semiconductor substrate 101 limited by isolation layers 102. Lightly doped drain (LDD) regions 105 having a shallow trench isolation (STI) structure can be formed in the active region of semiconductor substrate 101.

In order to form isolation layers 102, a pad insulating layer can be formed on and/or over semiconductor substrate 101 of a predetermined thickness and then etched by a photolithography process and an etching process using an isolation mask to form a trench. An oxide layer can then be buried in the trench and the pad insulating layer is removed to form isolation layers 102. When isolation layers 102 are formed, in order to form gate insulating layer 103 and gate electrode 104, gate insulating layer 103 and first polysilicon layer 104a, insulating layer 104b and second polysilicon layer 104b that compose gate electrode 104 are sequentially laminated on and/or over semiconductor substrate 101. The entire surface is coated with photoresist and a photolithography process such as exposure and development is performed to form a photoresist pattern that defines gate electrode 104. Gate electrode 104 is formed on and/or over semiconductor substrate 101 using the photoresist pattern as a mask by an etching process with gate insulating layer 103 interposed. LDD regions 105 can then be formed using gate electrode 104 as a mask. In accordance to embodiments, the method of fabricating a semiconductor device can be applied to a flash memory device, but is not limited thereto. In the case of the flash memory device, in gate electrode 104, first polysilicon layer 104a can serve as a floating gate in which electrons are actually stored and from which electrons are actually removed and second polysilicon layer 104c can serve as a control gate.

As illustrated in example FIG. 2B, tetraethyl orthosilicate (TEOS) layer 106a and first nitride layer 107a can be sequentially deposited on and/or over the resultant structure of substrate 101 including LDD regions 105.

As illustrated in example FIG. 2C, first spacers 106 composed of TEOS layer 106a and second spacers 107 composed of first nitride layer 107a can be formed on the sidewalls or surfaces of gate insulating layer 103 and gate electrode 104 by performing a reactive ion etch (RIE) on first nitride layer 107a and TEOS layer 106a. Source/drain impurities are then implanted into the entire surface of semiconductor substrate 101 using first and second spacers 106 and 107 and gate electrode 104 as masks to form source/drain regions 108 connected to LDD regions 105 in the surface of semiconductor substrate 101 on both sides of gate electrode 104.

As illustrated in example FIG. 2D, second spacers 107 can then be removed in a sequential process in order to prevent a void from being generated when a gap is filled with an interlayer insulating layer and to secure a margin.

As illustrated in example FIG. 2E, in order to prevent first spacers 106 from being removed by an undercut caused by wet etching in a non-salicide process and a salicide process when removing second spacers 107, second nitride layer 109a is grown on and/or over the resultant structure of substrate 101 using low pressure chemical vapor deposition (LP-CVD).

As illustrated in example FIG. 2F, ions are then implanted so that compressive stress is generated in second nitride layer 109a. All of the dopants that generate compressive stresses in second nitride layer 109a are used as the ions implanted into second nitride layer 109a. Ions of tetravalent elements are preferably implanted and Ge is preferably used. In order to easily implant ions into second nitride layer 109a, the ions can be tilted to be implanted at an angle between 5° and 10° from a virtual line substantially perpendicular to the entire uppermost surface of semiconductor substrate 101. Ge ions at a concentration between 1×10¹⁴ and 1×10¹⁶ atoms/cm³ are preferably implanted into the second nitride layer 109a by an energy level of between 5 KeV and 10 KeV. Second nitride layer 109a is then etched to form barrier nitride layers (as illustrated in example FIG. 2H) on sidewalls of first spacers 106 by a non-salicide process, thereby simplify processes.

As illustrated in example FIG. 2G, prior to forming the barrier nitride layers, oxide layer 110 is formed on and/or over second nitride layer 109a and then coated with a photoresist. A photolithograph process such as exposure and development is performed so that photoresist patterns PR that defines the salicide region is formed in the non-salicide region on and/or over oxide layer 110. Oxide layer 110 and second nitride layer 109a positioned in the salicide region including gate electrode 104 and first spacers 106 are wet etched using photoresist patterns PR as masks.

As illustrated in example FIG. 2H, second nitride layer 109a is then wet etched for removal together with oxide layer 110 to form barrier nitride layers 109 on sidewalls of first spacers 106. Use of barrier nitride layers 109 prevents removal of first spacers 106 during the wet etching in the non-salicide process and the wet etching in the salicide process.

In accordance with embodiments, barrier nitride layers 109 formed to protect spacers 106 formed on sidewalls of gate electrode 104 from the etching during the non-salicide process and the salicide process have compressive stresses caused by the ion implantation process so that the movement of the mobile ions is prevented. Therefore, due to barrier nitride layers 109 having such compressive stress, in the case of a flash memory device, it is possible to minimize influence on charge loss and charge gain and to improve the retention characteristic.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device comprising:
forming first spacers composed of a TEOS layer and second spacers composed of a first nitride layer on sidewalls of a gate electrode formed on a semiconductor substrate; and then
forming source/drain regions in the semiconductor substrate using the first and second spacers and the gate electrode as masks; and then
removing the second spacers; and then
depositing a second nitride layer on an entire surface of the semiconductor substrate; and then
implanting ions into the second nitride layer to generate compressive stress in the second nitride layer; and then
etching the second nitride layer to form barrier nitride layers on sidewalls of the first spacers.

2. The method of claim 1, wherein implanting the ions comprises implanting ions of a tetravalent element into the second nitride layer.

3. The method of claim 1, wherein implanting the ions comprises implanting the ions at an angle in a range between 5° and 10° relative to the uppermost surface of the semiconductor substrate.

4. The method of claim 1, wherein implanting the ions comprises implanting Ge ions at a concentration between 1×10¹⁴ and 1×10¹⁶ atoms/cm³ into the second nitride layer and at an energy level of between 5 KeV and 10 KeV.

5. The method of claim 1, wherein etching the second nitride layer comprises:
forming an oxide layer on the second nitride layer; and then
forming photoresist patterns on the oxide layer in a non salicide region; and then
etching the second nitride layer and the oxide layer existing in a salicide region using the photoresist patterns as a mask to form barrier nitride layers.

6. The method of claim 1, wherein the semiconductor device comprises a flash memory device.

7. A semiconductor device comprising:
a gate electrode formed on a semiconductor substrate;
first spacers composed of a TEOS layer formed on sidewalls of the gate electrode;
source/drain regions formed in the semiconductor substrate; and
barrier nitride layers having compressive stress formed on sidewalls of the first spacers.

8. The semiconductor device of claim 7, wherein the compressive stress is produced by performing implantation of ions.

9. The semiconductor device of claim 8, wherein the ions are implanted at an angle in a range between 5° and 10° relative to the uppermost surface of the semiconductor substrate.

10. The semiconductor device of claim 7, wherein the ions comprises ions of a tetravalent element.

11. The semiconductor device of claim 10, wherein the ions comprises Ge ions at a concentration between 1×10¹⁴ and 1×10¹⁶ atoms/cm³.

12. The semiconductor device of claim 7, wherein the semiconductor device comprises a flash memory device.

13. A method of fabricating a flash memory device comprising:
forming first spacers and second spacers on sidewalls of a gate electrode formed on a semiconductor substrate; and then
removing the second spacers; and then
forming a nitride layer on an entire surface of the semiconductor substrate including the gate electrode and the first spacers; and then
generating compressive stress in the nitride layer; and then
forming barrier nitride layers on sidewalls of the first spacers by etching the nitride layer.

14. The method of claim 13, wherein generating compressive stress in the nitride layer comprises implanting ions into the second nitride layer.

15. The method of claim 14, wherein implanting the ions comprises implanting ions of a tetravalent element into the second nitride layer at an angle in a range between 5° and 10° relative to the uppermost surface of the semiconductor substrate.

16. The method of claim 14, wherein implanting the ions comprises implanting Ge ions at a concentration between 1×10¹⁴ and 1×10¹⁶ atoms/cm³ into the second nitride layer at an energy level of between 5 KeV and 10 KeV and at an angle in a range between 5° and 10° relative to the uppermost surface of the semiconductor substrate

17. The method of claim 13, wherein forming the barrier nitride layers comprises:
forming an oxide layer on the nitride layer; and then
forming photoresist patterns on the oxide layer in a non salicide region; and then
etching the nitride layer and the oxide layer existing in a salicide region using the photoresist patterns as a mask.

18. The method of claim 13, wherein the first spacers are composed of a TEOS material.

19. The method of claim 13, wherein the second spacers are composed of a nitride material.

20. The method of claim 13, further comprising, after forming the first and second spacers but before removing the second spacers:
forming source/drain regions in the semiconductor substrate using the first and second spacers and the gate electrode as masks.
